(19) United States
(12) Patent Application Publication
(10) Pub. No.: US 2008/0264678 A1
(43) Pub. Date: Oct. 30, 2008

(54) Member for Interconnecting Wiring Films and Method for Producing the Same

(75) Inventors: Tomoo lijima, Tokyo (JP); Hiroshi Odaira, Kanagawa (JP); Tomokazu Shimada, Tokyo (JP); Akifumi Iijima, Kanagawa (JP)

Correspondence Address: LERNER, DAVID, LITTENBERG,;KRUMHOLZ & MENTLIK, 600 SOUTH AVENUE WEST, WESTFIELD, NJ, 07090, US

(73) Assignee: Tessera Interconnect Materials, Inc., San Jose, CA (US)

(21) Appl. No.: 11/662,024

(22) PCT Filed: Sep. 6, 2005
(86) PCT No.: PCT/JP05/16331

§ 371 Date: Jun. 25, 2008

(30) Foreign Application Priority Data
Sep. 6, 2004 (JP) 2004-257966

(51) Int. Cl. H05K 1/00; H05K 3/02

(52) U.S. Cl. 174/254; 29/847

(57) ABSTRACT

The connection resistance between a metal bump (8) and a metal layer (10) for forming a wiring film deposited later is further decreased, the connection stability is enhanced, the wiring path passing through the metal bump (8) is further shortened, the planarity is enhanced, and the metal bump (8) does not come out easily. A wiring film interconnecting member wherein a plurality of pillar-like metal bumps (8) composed of copper and having a cross-sectional area of the top surface smaller than that of the bottom surface and interconnecting the wiring films of a multilayer wiring board are buried in an interlayer insulation film (10) in such a way that at least one end projects. The upper surface of the interlayer insulation film (10) is so curved as to be high at a part in contact with the metal bump (8) and lower gradually as being farther therefrom.

### TECHNICAL FIELD

The present invention relates to a member that interconnects wiring films and, in particular, to a member which is suitable for interconnecting wiring films of a multilayer wiring substrate using metal bumps made of copper and a method for manufacturing such member.

### BACKGROUND ART

One approach to interconnecting wiring layers of a multiply wiring substrate is to use bumps made of copper, for example.

As an approach suitable for use in interconnection of wiring films to fabricate a multilayer wiring substrate, Japanese Patent Application No. 2002-233778, which resulted in Japanese Patent Laid-Open No. 2003-309370, discloses a member for interconnecting wiring films that has bumps in a conical shape, for example, embedded in a resin film serving as an interlayer insulation for interconnecting wiring films of a multilayer wiring board.

### Patent Document 1: JP 2003-309370 A (Japanese Patent Application No. 2002-233778)

### DISCLOSURE OF THE INVENTION

The approach described above can provide a member for interconnecting wiring films that enables a required number of layers to be pressed at a time, or enables bumps with a pitch smaller than the limit of pitch of an etching resist pattern to be disposed, or enables a fine wiring patterns to be formed on both sides of an insulating film by using a semi-additive method, or is capable of ensuring a fine pitch even when high bumps are used.

However, the conventional technique has a problem that it is difficult to improve the reliability of connection between the upper and bottom surfaces of a metal bump and metal layers made of copper that are provided on both surfaces of an interlayer insulating film through which the metal bump penetrates and are electrically connected to the upper and bottom surfaces of the metal bump.

This is because the connectivity is insufficient due to the relation between the thickness of the interlayer insulating film and the height of the metal bump or a gap is created between the interlayer insulating film and the wiring film formation metal layers and as a result the reliability of the interlayer insulation is insufficient.

Metal bumps are made from a metal layer of copper (copper film). Another problem is that the copper, which has been used as a material of the metal layer, contains impurity elements such as oxygen and therefore the reliability of connection between the metal bumps and the wiring film formation metal layer made of copper is insufficient.

This problem has been serious because it decreases the long-term reliability of a wiring substrate.

Furthermore, metal bumps have sometime come off from an interlayer insulating film during transportation of the member for interconnecting wiring, films. Metal bumps have been easily come off because they penetrate through the interlayer insulating film that holds the metal bumps and they cannot be supported from above or below.

The present invention has been made to solve the problem and an object of the present invention is to provide a member for interconnecting wiring films that improves the reliability of connection between a metal bump and a wiring film formation metal layer laminated later, ensures the planarity of a wiring substrate, and firmly holds the metal bump, and to provide a method for manufacturing such member.

According to claim 1, there is provided a member for interconnecting wiring films for interconnecting wiring films of a multilayer substrate, in which multiple metal bumps made of copper having the shape of a pillar whose top surface has a cross-sectional area smaller than that of the bottom surface are embedded in an interlayer insulating film in such a manner that at least one end of each metal bump protrudes through the interlayer insulating film, characterized in that the top surface of the interlayer insulating film is curved in such a manner that portions of the top surface that contact the metal bumps are high and the height of the top surface decreases with distance from the metal bumps.

According to claim 2, there is provided a member for interconnecting wiring films in which multiple metal bumps made of copper having the shape of a pillar whose top surface has a cross-sectional area smaller than that of the bottom surface are embedded in an interlayer insulating film in such a manner that at least one end of each metal bump protrudes through the interlayer insulating film, characterized in that the copper of the metal bumps has a purity of greater than or equal to 99.9%, the sum of the amounts of protrusions of each metal bump from the surfaces of the interlayer insulating film is in the range from 15 to 45 μm, and the average surface roughness of the top and bottom surfaces of each metal bump is less than or equal to 0.5 μm.

According to claim 3, in the member for interconnecting wiring films as set forth in claim 1 or 2, the interconnecting insulating film has a three-layer structure including a non-thermoplastic film serving as a core and thermoplastic polyimide resin films formed on both sides of the non-thermoplastic film, and each of the thermoplastic polyimide resin films has a thickness in the range from 1 to 8 μm.

According to claim 4, in the member for interconnecting wiring films as set forth in claim 3, the non-thermoplastic film is made of non-thermoplastic polyimide resin having a thickness in the range from 10 to 70 μm.

According to claim 5, the member for interconnecting wiring films is made of a glass-based epoxy resin film having a thickness in the range from 30 to 80 μm.

According to claim 6, there is provided a method for manufacturing a member for interconnecting wiring films, including the steps of: forming a resist film having a predetermined pattern on a surface of a stack consisting of a bump formation metal layer of copper and a carrier layer on the surface opposite to the surface on which the carrier layer is provided; etching the bump formation metal layer by using the resist film as a mask to form multiple metal bumps having the shape of a pillar protruding on the carrier layer; removing the resist film; pressing an interlayer insulating film against the metal bumps from the top surface side so that the metal bumps penetrate into the interlayer insulating film; applying pressure on the top surface; polishing the interlayer insulating film to expose the top faces of the bumps; and removing the carrier layer, wherein the bump formation metal layer is made of copper having a purity of equal to or greater than 99.9% and the top and bottom surfaces have an average surface roughness of 0.5 μm or less.

According to claim 7, there is provided a method for manufacturing member for interconnecting wiring films, including the steps of: forming a resist film having a predetermined pattern on a surface of a stack of a bump formation metal layer of copper and a carrier layer on the side opposite to the surface on which the carrier layer is provided; etching the bump formation metal layer by using the resist film as a mask to form multiple metal bumps having the shape of a pillar protruding on the carrier layer; removing the resist film; pressing an interlayer insulating film against the metal bumps from the top surface side; polishing the interlayer insulating film to expose the top faces of the bumps; and removing the carrier layer; wherein the carrier layer is a carrier film on which an adhesive layer whose adhesive force is decreased by irradiation with UV (ultraviolet) light is formed, and the method includes, between the step of removing the resist film and the step of pressing the interlayer insulating film against the metal bumps from the top surface side, the step of irradiating the carrier layer with UV light from the metal bump side to reduce its adhesive force, and during or before the step of removing the carrier, the carrier is irradiated with UV light.

According to claim 8, in the method for manufacturing a member for interconnecting wiring films as set forth in claim 6 or 7, the interlayer insulating film has a three-layer structure including a non-thermoplastic film as the core and thermoplastic polyimide resin films or epoxy modified resin films formed on the both sides of the core non-thermoplastic film, and the thermoplastic polyimide resin film or epoxy modified resin film on each side has a thickness in the range between 1 to 8 μm.

According to claim 9, in the method for manufacturing a member for interconnecting wiring films as set forth in claim 8, the non-thermoplastic resin film serving as the core is made of glass epoxy having a thickness in the range from 30 to 100 μm.

According to claim 10, in the method for manufacturing a member for interconnecting wiring films as set forth in claim 6 or 7, the interlayer insulating film is made of glass epoxy having a thickness in the range from 30 to 100 μm.

According to claim 11, in the method for manufacturing a member for interconnecting wiring films as set forth in any of claims 6, 7, 8, 9, and 10, a polyester film having a thickness in the range from 25 to 50 μm is used as the resin film of the carrier layer and an adhesive is used that has a thickness in the range from 2 to 10 μm, an initial adhesive force in the range from 10 to 30 N/25 mm, and an adhesive force in the range of 0.05 to 0.15 N/25 mm after UV (ultraviolet) light irradiation.

In the member for interconnecting wiring films according to claim 1, the top surface of the interlayer insulating film is curved in such a manner that portions contacting metal bumps are high and portions farther from the metal bumps are lower and therefore the force that holds the metal bumps is enhanced. In particular, since the interlayer insulating sheet is elastic, the curve of the portions of the sheet that contact the side surface of the bumps has the effect of pressing the bumps with elastic force to prevent the metal bumps from coming off.

Thus, the problem that metal bumps come off from the member for interconnecting wiring films can be solved.

In the member for interconnecting wiring films according to claim 2, the purity of copper of the metal bumps is as high as 99.9%. Since copper with that high purity is used to form the metal bumps instead of copper containing impurity elements such as oxygen, the problem of insufficient reliability of connection can be alleviated.

The sum of the amounts of protrusions of the ends (top and bottom ends) of each metal bump from the surfaces of the interlayer insulating film is 15 μm or more, the wiring film formation metal layer of copper laminated subsequently on both sides of the member for interconnecting wiring films can be brought into adequate pressure contact with each metal bump. Thus, the reliability of the connection can be further ensured.

If the sum of the amounts of protrusion of the metal bumps from top and bottom ends of the interlayer insulating film is smaller, sufficient pressure-contact cannot be provided by the pressure applied for the lamination and imperfect contact may result because the length of the protrusion of the metal bumps is insufficient. Also, recesses may be produced in the surface and thus the surface planarity can be impaired. Various experiments have shown that a thickness of 15 μm or more can avoid these problems and ensure reliable connection.

Since the sum of the amounts of protrusion is less than or equal to 45 μm, the planarity of the surfaces of the member for interconnecting wiring films is not impaired when the interlayer insulating film a wiring film formation metal layer are subsequently laminated together.

If the amount of protrusion is larger, portions of the wiring film formation metal layer on which the metal bumps 8 are disposed would not completely be depressed but remain protruded after the wiring layer formation metal layer is laminated in a subsequent process, resulting in poor planarity of the wiring substrate. This problem is unignorable for a wiring substrate on which bare ICs or LSI that especially requires planarity are mounted. Various experiments have shown that a thickness of not greater than 45 μm can avoid the problem: bumps 8 are completely depressed and planarity is not impaired.

Since the average surface roughness of the top and bottom surfaces of each metal bump is less than or equal to 0.5 μm, microscopic gaps between the metal bumps and a wiring film formation metal layer subsequently laminated on them are not formed. Consequently, reliable connectivity can be achieved. An average surface roughness of 0.5 μm or less can be readily achieved by extending a metal such as a copper by rolling to form a metal layer for forming metal bumps.

In the member for interconnecting wiring films according to claim 3, the interlayer insulating film has a three-layer structure including a non-thermoplastic film serving as a core and thermoplastic polyimide resin films or epoxy modified resin films provided on both sides of the core non-thermoplastic film. The non-thermoplastic polyimide resin film serving as the core can ensure the force of holding bumps.

The thermoplastic polyimide resin films or epoxy modified resin films provided on both surfaces can ensure the adhesive force required for adhering wiring film formation metal layers to the surfaces.

Since the thickness of the thermoplastic polyimide resin film or the epoxy modified resin film is 1 μm or more, the film can absorb roughness of the surface of a wiring film formation metal layer made of copper, for example, provided on each surfaces to eliminate the possibility of a gap being produced between the wiring film formation metal layer and metal bumps after lamination.

If the thermoplastic polyimide resin film is thinner, roughness of the surface of a wiring film formation layer subsequently laminated on the member for interconnecting wiring films cannot sufficiently be absorbed and therefore a sufficiently close contact between the wiring film formation metal layer and the interlayer insulating film cannot be achieved. Experiments have shown that a thickness equal to or greater than 1 μm of a thermoplastic polyimide resin film can ensure adequate contact between a wiring film formation metal layer and an interlayer insulating layer.

Since the thickness of the thermoplastic polyimide resin film is 8 μm or less, an adequate strength and hardness required of the base for a wiring film formation layer subsequently laminated can be ensured.

If the thermoplastic polyimide resin film is thicker, an adequate force of adhesion with the wiring film formation metal layer can be achieved but the strength and hardness required of the base material of a wiring substrate decrease. Experiments have shown that a thermoplastic polyimide resin film or an epoxy modified resin film having a thickness of 8 μm or less can ensure an adequate strength and hardness as the base material of a wiring substrate subsequently laminated.

In the member for interconnecting wiring films according to claim 4, the non-thermoplastic film serving as the core of the interlayer insulating film is made of a non-thermoplastic polyimide resin having a thickness of 10 μm or more. Therefore, an adequate strength can be ensured. Non-thermoplastic polyimide resin films have high heat resistances and mechanical strengths and therefore can ensure an adequate strength required of a member for interconnecting wiring films.

The thickness of the non-thermoplastic polyimide resin film serving as the core is 70 μm or less, which prevents a significant increase of thicknesses of the member for interconnecting wiring films and a multilayer wiring substrate that uses the member for interconnecting wiring films.

In the member for interconnecting wiring films according to claim 5, the non-thermoplastic film serving as the core of the interlayer insulating film is made of glass epoxy resin having a thickness of 30 μm or more, which can ensure an adequate strength. Since glass epoxy resins have relatively high heat resistances and mechanical strengths, a thickness of 30 μm or more can adequately ensure strength required of a member for interconnecting wiring films.

The thickness of the glass epoxy resin film serving as the core is 100 μm or less, which prevents a significant increase of thicknesses of the member for interconnecting wiring films and a multilayer wiring substrate that uses the member for interconnecting wiring films.

In the method for manufacturing a member for interconnecting wiring films according to claim 6, a bump formation metal layer is laminated on a carrier layer, the bump formation metal layer is selectively etched by using a patterned resist film as a mask to form metal bumps, then the resist film is removed, an interlayer insulating film is provided on the carrier layer in such a manner that the metal bumps penetrate through the interlayer insulating film, and then the carrier layer is removed to provide a member for interconnecting wiring films. The bump formation metal layer is made of copper having a purity of 99.9% or more, therefore a junction with a low defect rate and highly reliable electric connectivity can be provided when the member for interconnecting wiring films is used to fabricate a multilayer wiring substrate.

Both surfaces of the bump formation metal layer have an average surface roughness of 0.5 μm or less. Accordingly, an average surface roughness of 0.5 μm of the top and bottom surfaces of each metal bump can be achieved.

Therefore, the defect rate in the junction between the metal bumps and a wiring film formation metal layer subsequently laminated is reduced and consequently the reliability of the connection can be provided. Thus, the reliability of connection can be improved.

In the method for manufacturing a member for interconnecting wiring films according to claim 7, the carrier layer is made of a material whose adhesive force decreases under UV light and the carrier layer is irradiated with UV light before or during removal of the carrier layer. Therefore, the carrier layer can be removed with a weaker removal force.

Thus, the carrier layer can be removed without applying a considerably large force to the member for interconnecting wiring films. Consequently, deformation such as a bend of the member for interconnecting wiring films during the removal of the carrier layer can be prevented.

In the method for manufacturing a member for interconnecting wiring films according to claim 8, the interlayer insulating film has a three-layer structure including a non-thermoplastic film serving as a core and thermoplastic polyimide resin films or epoxy modified resin films provided on both side of the non-thermoplastic film. Therefore, the force of holding bumps can be ensured by the non-thermoplastic polyimide resin film serving as the core as stated above.

Since the thermoplastic polyimide resin films or epoxy modified resin films are provided on both sides, an adhesive force required for adhering wiring film formation metal layer laminated on both sides can be ensured.

Since the thermoplastic polyimide resin film or the epoxy modified resin film has a thickness of greater than or equal to 1 μm, surface roughness of a wiring film formation layer made of a metal, for example copper, laminated on both sides can be absorbed. Therefore, the possibility of a gap being created between the wiring film formation metal layer laminated and metal bumps can be prevented.

Furthermore, since the thickness of the thermoplastic resin film is less than or equal to 8 μm, an adequate strength and hardness required of the base for a wiring film formation layer subsequently laminated can be ensured.

In the method for manufacturing a member for interconnecting wiring films according to claim 9, a non-thermoplastic polyimide resin film having a thickness of 10 μm or more is used as the non-thermoplastic resin film serving as the core of the interlayer insulating film and therefore an adequate strength can be ensured. Also, the thickness of the film is less than or equal to 65 μm, which has the effect of preventing a significant increase of the thicknesses of the member for interconnecting wiring films and a multilayer substrate that uses the member for interconnecting wiring films.

In the method for manufacturing a member for interconnecting wiring films according to claim 10, a glass epoxy resin film with a thickness of 30 μm is used as the interlayer insulating film. Therefore, an adequate strength can be ensured. Also, the thickness of the film is less than or equal to 100 μm, which has the effect of preventing an significant increase of the thickness of the member for interconnecting wiring films and a multilayer substrate that uses the member for interconnecting wiring films.

In the method for manufacturing a member for interconnecting wiring films according to claim 11, the resin film of the carrier layer has a thickness in the range from 25 to 50 μm and the adhesive has a thickness in the range from 2 to 10 μm, an initial adhesive force of 10 to 30 N/25 mm, and an adhesive force in the range from 0.05 to 0.15 N/25 mm after UV (ultraviolet) light irradiation. Therefore, when the carrier layer is required, the carrier layer has an adhesive force strong enough for preventing the carrier layer from coming off from the member for interconnecting wiring films; whereas when the carrier layer is to be removed, the adhesive force can be sufficiently weaken so that it can be removed without needing a strong force.

### BRIEF DESCRIPTION OF DRAWINGS

FIGS. 1(A) to 1(G) are cross-sectional view showing step by step a method for manufacturing an member for interconnecting wiring films according to a first embodiment of the present invention, wherein FIG. 1(G) is a cross-sectional view of the member for interconnecting wiring films according to the first embodiment;

FIG. 2 is a cross-sectional view of an interlayer insulating film used for manufacturing a member for interconnecting wiring films;

FIGS. 3(A) and 3(B) are cross-sectional views showing step by step an example of a method for manufacturing a wiring substrate using the member for interconnecting wiring films shown in FIG. 1(F);

FIGS. 4(A) to 4(G) are cross-sectional views showing step by step a method for manufacturing member for interconnecting wiring films according to a second embodiment step of the present invention;

FIGS. 5(A) and 5(B) are cross-sectional views showing a method for manufacturing a multilayer wiring substrate using an member for interconnecting wiring films according to the present invention; and

FIG. 6 is a cross-sectional view showing a member for interconnecting wiring films according to a third embodiment of the present invention step by step.

### DESCRIPTION OF SYMBOLS

2 . . . Bump formation metal layer (copper)
4 . . . Carrier layer
4a . . . Resin film
4b . . . Adhesive layer
8 . . . Metal bump (copper)
10 . . . Interlayer insulating film
10a . . . Non-thermoplastic polyimide film
10b . . . Thermoplastic polyimide film
12 . . . Wiring film formation metal layer
14 . . . Wiring film
60 . . . Interlayer insulating film
62 . . . Metal layer (cylindrical)

### BEST MODE FOR CARRYING OUT THE INVENTION

A first best mode of a member for interconnecting wiring films is a connecting member in which multiple metal bumps made of copper having the shape of a pillar whose top surface has a cross-sectional area smaller than that of the bottom surface are embedded in an interlayer insulating film in such a manner that at least one end of each metal bump protrudes through the interlayer insulating film, characterized in that the top surface of the interlayer insulating film is curved in such a manner that portions of the top surface that contact the metal bumps are high and the height of the top surface decreases with distance from the metal bumps.

This can be provided as follows: a bump formation metal layer made of copper adhered with a carrier layer is provided, the bump formation metal layer is patterned using photo-etching to form metal bumps, an interlayer insulating film is provided on the surface of the carrier layer where the bumps have been formed in such a manner that the metal bumps pass through the interlayer insulating film, and then the carrier layer is removed.

The copper of the metal bumps, or the metal layer forming the metal bumps, preferably has a purity of 99.9% or higher. Preferably, the interlayer insulating film has a non-thermoplastic polyimide resin film at its core to ensure adequate strength required of a member for interconnecting wiring films and includes thermoplastic polyimide resin films laminated on both surfaces of the core non-thermoplastic polyimide resin film in order to provide adhesion with wiring film formation metal layers laminated on both surfaces of the member for interconnecting wiring films. That is, the interlayer insulating film preferably has a three-layer structure.

The thickness of the thermoplastic polyimide films on both sides is preferably in the range from 1 to 8 μM. An epoxy modified adhesive may be used instead of the thermoplastic polyimide resin film to obtain a similar effect.

Another preferable core is a glass epoxy resin film. If a non-thermoplastic polyimide resin film is used as the core, the thickness is preferably in the range from 10 to 65 μm. If a glass epoxy resin film is used, the thickness is preferably in the range from 30 to 100 μm.

The carrier layer on which the bump formation metal layer is placed during the process of manufacturing the member for interconnecting wiring films is preferably made of a material whose adhesive force decreases under UV light. In particular, the adhesive is preferably a material having a thickness in the range from 2 to 10 μm, an initial adhesive force between 10 and 30 N/25 mm, and an adhesive force after irradiation with UV (ultraviolet) light between 0.05 and 0.15 N/25 mm.

### FIRST EMBODIMENT

The present invention will be described below in detail with respect to embodiments shown in the accompanying drawings.

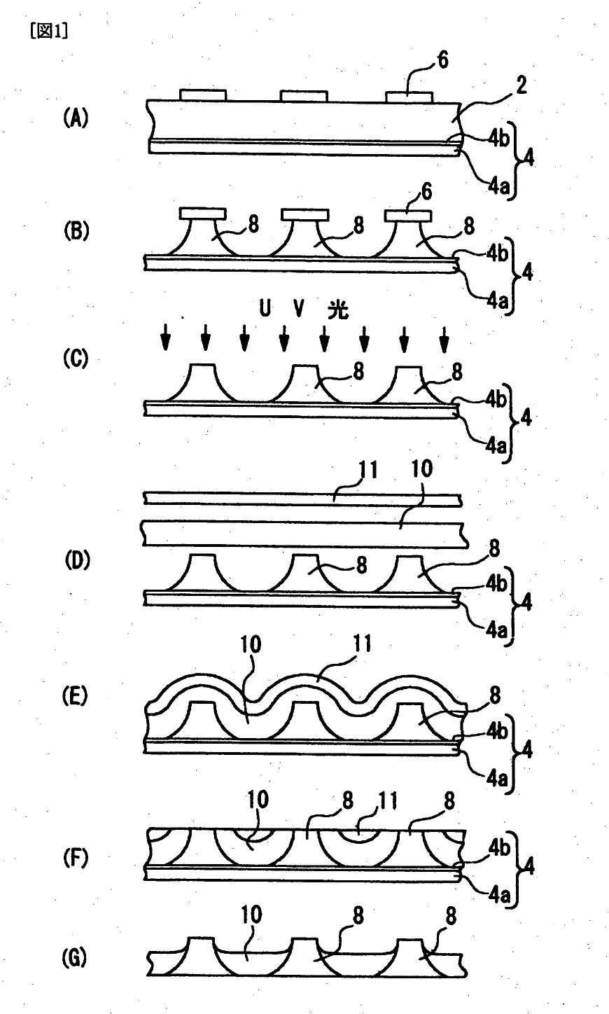

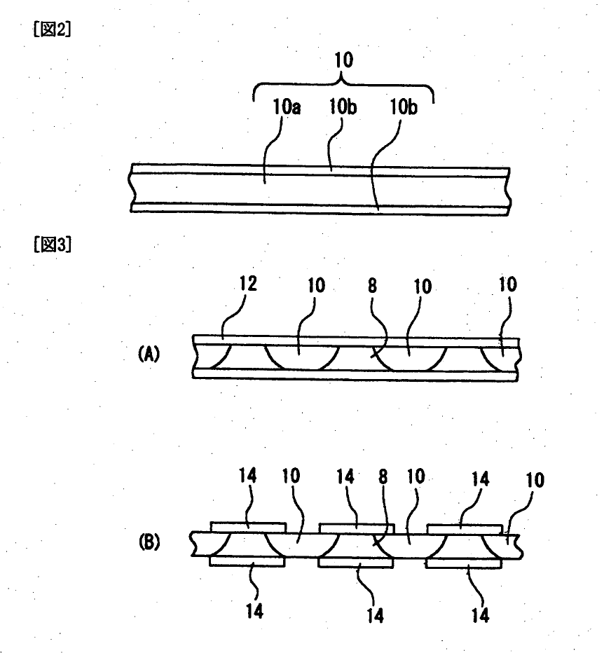

FIGS. 1(A) to 1(F) are cross-sectional diagrams showing a method for fabricating a multilayer wiring substrate of a first embodiment step by step.

(A) First, a carrier layer 4 bonded with one principal surface of a bump formation metal layer 2 made of copper is provided. A photoresist film 6 is provided on the other principal surface of the bump formation metal layer 2. Then, the photoresist film 6 is exposed to light and developed to pattern the resist film 6. FIG. 1(A) shows the patterned photoresist film 6.

The bump formation metal layer 2 may be made of deoxidized copper having a copper purity of 99.9% or higher. By using copper with such a high purity, highly reliable connectivity of the junction between the copper of metal bumps and the copper of wiring film formation metal layers with a low defect rate can be achieved when the wiring film formation metal layer is laminated on both sides of the completed member for interconnecting wiring films.

The average roughness of the bump formation metal layer 2 is made 0.5 μm or less. If the surface roughness of both of the top and bottom sides of the metal bump is high, asperities of the surface of junction between the metal bump and the wiring film formation metal layer could not completely be eliminated and minute defects would remain at the junction between metal bump and the wiring film formation metal layer of copper laminated on both side of the completed member for interconnecting wiring films and it would be difficult to ensure sufficient reliability of connection. An average surface roughness of 0.5 μm or less minimizes the defect rate in the copper-copper joint surface; therefore sufficiently high reliability can be achieved.

The carrier layer 4 consists of a resin film 4a with a thickness between 25 and 50 μm serving as the base and an adhesive layer 4b provided on one principal surface of the resin film 4a. The adhesive layer 4b is made of a material whose adhesive force decreases by exposure to UV light. In particular, the adhesive layer 4b preferably has an initial adhesive force in the range from 10 to 30 N/25 mm and an adhesive force after exposure to UV light in the range from 0.05 to 0.15 N/25 mm.

A material whose adhesive force decreases by exposure to UV light is used so that the carrier layer 4 has an adhesive force sufficiently high for preventing bumps from coming off during a process such as a bump etching process that requires a strong adhesive force and the adhesive force can be reduced by UV light to a force sufficiently weak for the carrier layer 4 to be readily removed when it is no longer required.

The thickness of the carrier film 4a is chosen to be a value in the range from 25 to 50 μm because if the thickness is less than 25 μm, it is difficult to ensure adequate strength of the member for interconnecting wiring films and the carrier film 4a will be prone to deformation during various processes and transportation. If the thickness is greater than or equal to 50 μm, the member for interconnecting wiring films can be deformed when the carrier layer 4 is removed and, as a result, bumps can come off or residual deformation of the member for interconnecting wiring films can occur.

The thickness of the resin film 4a and the adhesive layer 4b is chosen to be 25 μm, for example, and the thickness of the adhesive layer 4b is chosen to be a value in the range from 2 to 10 μm, for example. This is because if the thickness is less than 2 μm, adequate adhesion cannot be ensured and metal bumps can come off under mechanical stress applied to the adhesive layer 4b by a spray of liquid during etching or under stress applied during transportation. If the thickness of the adhesive layer 4b is greater than 8 μm, the carrier layer 4 would be squashy and would not adequately serve as the base for metal bumps and, as a result, metal bumps can be tilted or displaced.

(B) Then, the bump formation metal layer 2 of copper is etched by using the photoresist film 6 as a mask to form metal bumps 8 as shown in FIG. 8(B). The metal bump 8 is conical in shape; the cross-sectional area of the bump 8 tapers down toward the top (the top face of the metal bump 8).
(C) The member for interconnecting wiring films is irradiated with UV light from the metal bump 8 formation side as shown in FIG. 1(C) to reduce the adhesive force of the adhesive layer 4b.

The UV light is applied from the metal bump 8 formation side so that the metal bumps 8 serve as a mask during exposure to the UV light to prevent the adhesive layer 4b of the carrier layer 4 from being exposed to the UV light and losing adhesive force. Furthermore, the portions of the adhesive where the bumps are not formed harden and facilitate fixation of fixing the metal bumps 8.

(D) Then, an interlayer insulating film 10 and a peeling sheet 11 made of a synthetic resin are applied to the member for interconnecting wiring films on the metal bump 8 formation side as shown in FIG. 1(D). The interlayer insulating film 10 has a three-layer structure as shown in FIG. 2.

In particular, the interlayer insulating film 10 consists of a non-thermoplastic polyimide resin film 10a as its core and thermoplastic polyimide resin films 10b provided on both principal surfaces of the non-thermoplastic polyimide resin film 10a. The thickness of the core non-thermoplastic polyimide resin film 10a is in the range from 10 to 50 μm and the thickness of the thermoplastic polyimide resin film 10b on each principal surface is in the range from 1 to 8 μm.

The thickness of the non-thermoplastic polyimide resin film 10 that is the core of the interlayer insulating film is chosen to be a value in the range from 10 to 50 μm because a thickness of at least 10 μm can ensure an adequate strength of the member for interconnecting wiring films. Thickness not greater than 50 μm is chosen because this avoids increase of the thicknesses of the member for interconnecting wiring films and a multilayer wiring substrate that uses the member for interconnecting wiring films.

The thickness of the thermoplastic polyimide resin film 10b on each principal surface is chosen to be a value in the range from 1 to 8 μm because a thinner thermoplastic polyimide film cannot provide an adequate strength of adhesion between the thermoplastic polyimide resin film 10b and the wiring film formation metal layer made of copper, for example, that is provided on both side of the member for interconnecting wiring films after completion. Experiments have shown that a thickness of 1 μm or thicker can ensure adequate adhesion between the thermoplastic polyimide resin film 10b and the wiring film formation metal layer made of a material such as a copper provided on both sides.

If the thermoplastic polyimide resin film 10b is thicker, the toughness and good electric properties of the core non-thermoplastic polyimide resin will degrade. A required minimum thickness of the thermoplastic polyimide should be chosen.

(E) Then, pressure is applied to the interlayer insulating film 10 and the peeling sheet 11 from the top through a cushioning material (not shown) to cause the interlayer insulating sheet 10 and the peeling sheet 11 to conform to the carrier film and the metal bumps 8 as shown in FIG. 1(E). They can be more effectively made conform by applying hot press.
(F) Then, the peeling sheet 11 is polished by mainly targeting protrusions nearly up to the level of the peeling sheet 11 to expose the top face of the metal bumps 8 as shown in FIG. 1(F). A roll polishing machine, which is capable of polishing continuously, may be used in stead of grinding wheel.

Thus, the top surface of the interlayer insulating film 10 curves in such a manner that portions contacting the metal bumps are high and the height of the top surface gradually decreases with distance from the contact surfaces as shown in FIG. 1(F).

This shape enhances the force of holding the metal bumps. Since the interlayer insulating sheet is elastic, the bumps can be forced down by the elastic force of sheet which is curved in such a manner that the portions of the sheet that are in contact with the bump conform to the sides of the bump. Therefore, the metal bumps are prevented from coming off.

Here, each bump 8 of copper should protrude above the interlayer insulating film 10 by a height in the range from 15 to 45 μm.

The reason is as follows.

If the amount of protrusion of the metal bump 8 from the interlayer insulating film 10 is smaller, shrinkage of the metal bump 8 under pressure applied for laminating the wiring film formation metal layer to the member for interconnecting wiring films could not sufficiently be compensated by the amount of protrusion of the metal bump 8 and poor connection may result. In addition, recesses may be produced in the surface and thus the surface planarity can be impaired.

Various experiments have shown that a thickness of μm or more can avoid these problems and can ensure reliable connection. For this reason, a protrusion of 15 μm or ore is chosen.

If the amount of protrusion is larger, portions of the wiring film formation metal layer on which the metal bumps 8 are located would not completely be depressed but remain projected after the wiring layer formation metal layer is laminated in a subsequent process, resulting in poor planarity of the wiring substrate. This problem is unignorable for a wiring substrate on which bare ICs or LSI which especially requires planarity. Various experiments have shown that a thickness of not greater than 45 μm can avoid the problem, can completely depress the bumps 8, and does not impair planarity. For this reason, an amount of protrusion of 45 μm or less is chosen.

The amount of protrusion of the metal bump 8 from the interlayer insulating film 10 can be made in the range from 15 to 45 μm by choosing a thickness of the bump formation metal layer 2 somewhat less than the thickness of the interlayer insulating film 10, which is in the range from 15 to 45 μm.

(G) Then, the member for interconnecting wiring films is irradiated again with UV light from the carrier sheet side to harden the adhesive layer on which the bumps are formed, thereby reducing its adhesive force. Then, the carrier layer 4 and the peeling sheet 11 are removed. As a result, the member for interconnecting wiring films is completed as shown in FIG. 1(G).

Since the adhesive force of the adhesive layer 4b of the carrier layer 4 is reduced by the irradiation with the UV light, the carrier layer 4 can be removed with a quite weak force. This can avoid the problem of deforming the member for interconnecting wiring films under a strong force applied in order to remove the carrier layer 4.

A film such as polyethylene or polypropylene that does not adhere to any resins is used so that the sheet can be readily removed.

It should be noted that the peeling process may be performed in parallel with irradiation with UV light. That is, peeling may be performed while applying UV light, thereby increasing the processing speed and reducing manufacturing costs.

### [Variations]

A glass epoxy resin film may be used as the interlayer insulating film 10 in the embodiment described above.

In that case, the thickness of the glass epoxy resin film should be in the range from 30 to 100 μm.

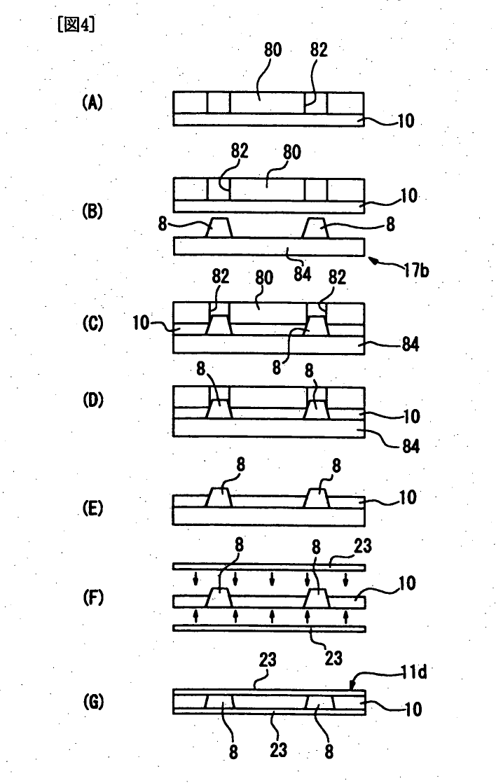

FIGS. 3(A) and 3(B) are cross-sectional views illustrating step by step a method for manufacturing a two-layer wiring substrate using the member for interconnecting wiring films shown in FIG. 1(F).

(A) A wiring film formation metal layer 12 is placed on each side of the member for interconnecting wiring films as shown in FIG. 3(A) and pressure and heat are applied to laminate them together.
(B) Then, the wiring film formation metal layers 12 are patterned by photo-etching. As a result, a wiring film 14 of copper 14 is formed as shown in FIG. 3(B).

### SECOND EMBODIMENT

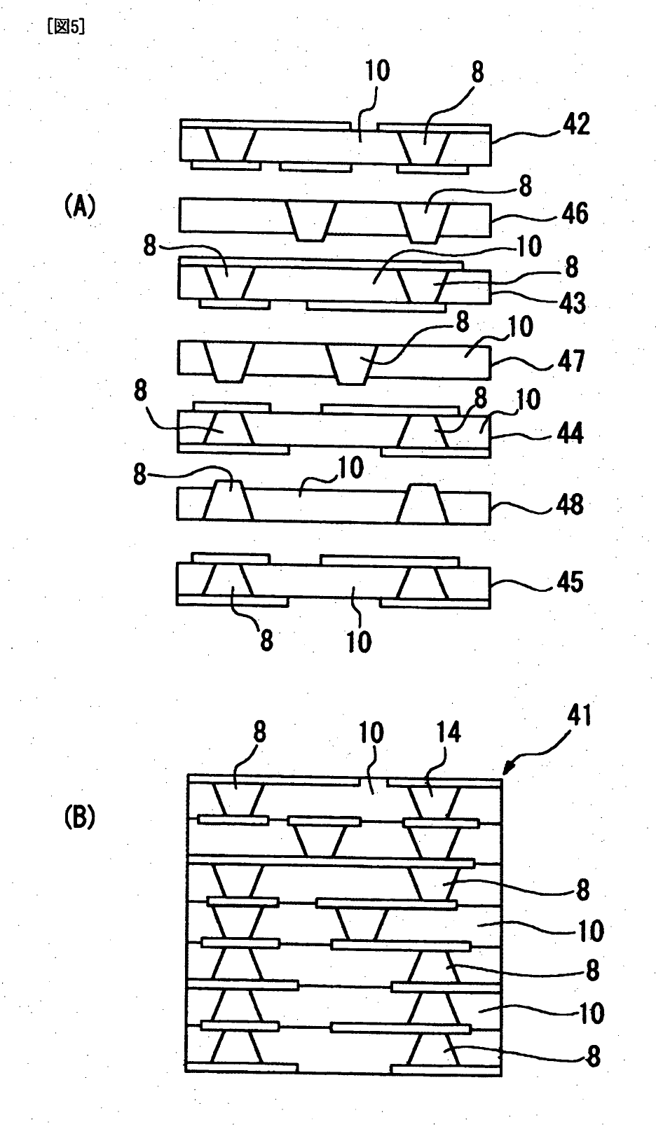

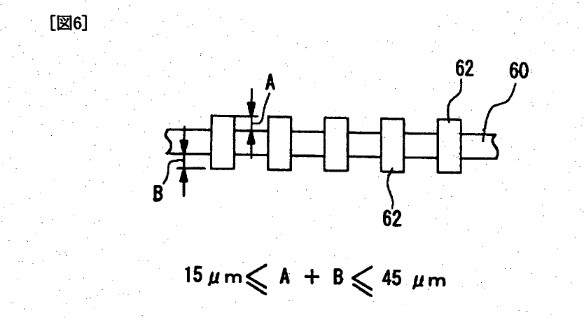

FIGS. 4(A) to 4(G) are cross-sectional views illustrating step by step a method for manufacturing a wiring substrate according to a second embodiment of the present invention.

(A) First, an interlayer insulating film 10 on which an upper mold 100 is laminated is provided as shown in FIG. 4(A). The upper mold 100 is made of a metal (for example SUS) or a resin and has bump receiving cavities 82 corresponding to metal bumps (8), which will be described later. The bump receiving cavities 62 may be formed by applying a photoresist on the upper mold 100 adhered to the interlayer insulating film 10, exposing to light and developing the photoresist to pattern it to produce a mask film, and etching the upper mold 100 by using the photoresist film as a mask. The bump receiving cavities 82 may be formed before the upper mold 100 is adhered to the interlayer insulating film 10.
(B) Then, a member for interconnecting wiring films 17b consisting of a lower mold 84 made of a metal (for example SUS) or a resin and metal bumps 8 formed on the lower mold 84 is provided as shown in FIG. 4(B). The upper mold 100 is held above the surface of the member 17b on which the bumps 8 are formed in such a manner that the interlayer insulating film 10 faces downward and each of the bump receiving cavities 82 aligns its corresponding metal bump 8.
(C) The upper mold 100 is pressed onto the lower mold 84 until the metal bumps pierce the interlayer insulating film 10 as shown in FIG. 4(C). This piercing produces resin chips which contaminate the surface of the interlayer insulating film 10. Preferably, the surface is cleaned after this process.
(D) The upper mold 100 is removed as shown in FIG. 4(D).
(E) The lower mold 84 is removed as shown in FIG. 4(E).

Thus, the member for interconnecting wiring films is completed. The member for interconnecting wiring films has been fabricated using the mold 84 instead of a carrier layer 4.

In this way, a member for interconnecting wiring films can be manufactured without using a carrier layer 4.

To form a wiring film on each side of the member for interconnecting wiring films shown in FIG. 1(F), a wiring film formation metal layer must be formed. This is formed in the step shown in FIGS. 4(F) and 4(G).

(F) Then, a wiring film formation metal layer 23 is faced to each side of the interlayer insulting film 10 penetrated by the metal bumps 8 as shown in FIG. 4(F).
(G) The wiring film formation metal layers 23 are laminated to the interlayer insulating film 10 under heat and pressure. Thus, a wiring substrate 11d is formed.

FIGS. 5(A) and 5(B) are cross-sectional views illustrating step by step a method for fabricating a multilayer wiring substrate using a member for interconnecting wiring films of the invention. In this embodiment, the multilayer wiring substrate 41 is formed by laminating press in one step.

(A) First, three member for interconnecting wiring films 46-48 are placed between four dual-sided wiring substrates 42-45 (FIG. 5(A)).
(B) They are then pressed under a high temperature at once. Thus, a multilayer wiring substrate 41 is completed (FIG. 5(B)).

Each of the four dual-sided wiring substrates 42-45 can be formed by performing all the steps of the process of the first embodiment and then patterning a wiring film formation copper foil 23. Each of the three member for interconnecting wiring films 46-48 can be formed by performing part (FIGS. 1(A) to 1(F)) of the process of the first embodiment.

### THIRD EMBODIMENT

FIG. 6 is a cross-sectional view of a member for interconnecting wiring films according to a third embodiment of the present invention.

While the metal bumps (8) of the member for interconnecting wiring films of the first embodiment shown in FIG. 1(F) have a conical shape, they do not necessarily need to have a conical shape. For example, metal bumps may have the shape of a pillar with a uniform cross-section from the top to bottom as shown in FIG. 6. While the bottom surface of each metal bump (8) in the member for interconnecting wiring films of the embodiment shown in FIG. 1(G) is flush with (on the same pane as) the bottom surface of the interlayer insulating film (10), they do not necessarily need to be flush with each other. The upper end of the metal bump 62 may project from the top surface of the interlayer insulating film 60 and the lower end may project from the bottom surface of the interlayer insulating film 60.

In that case, the sum of the amount of protrusion A of the metal bump 65 from the top surface of the interlayer insulating film 60 and the amount of protrusion B of the metal bump 62 from the bottom surface of the interlayer insulating film 60 should be in the range from 15 to 45 μm.

The remaining portions of the member for interconnecting wiring films of the third embodiment are the same as the member for interconnecting wiring films of the first embodiment shown in FIG. 1(G).

Metal bumps may have other shape such as a truncated cone shape, quadrangular pyramid shape, or a flat biconvex shape.

The above-described embodiments of the present invention have focused on various members that interconnect wiring films and methods for manufacturing them. However, the principle of the present invention can be directly applied to a member used for providing an interconnection member that interconnects conductors of microelectronic components. For example, the principle of the present invention can be applied to a chip substrate or an interconnection substrate such as a chip substrate, a test substrate, an interposer and a circuit panel that has multiple metal bumps projecting from at least one surface of the chip substrate, a circuit panel, or another interconnection substrate. In such a chip substrate, interconnection substrate, or circuit panel, the apex or end each metal bump on either or both sides of the substrate is intermediately connected to a contact of another microelectronic component tentatively, namely by press-contact, or permanently by metal bond.

### INDUSTRIAL APPLICATION

The present invention relates to a member for interconnecting wiring films and a manufacturing method thereof. In particular, the present invention finds industrial application in a member for interconnecting wiring films suitable for interconnecting wiring films of a multilayer wiring substrate using metal bumps made of copper and methods for manufacturing such members.

1. A member for interconnecting wiring films, comprising an interlayer insulating film having a bottom surface and a top surface opposite to the bottom surface, and a plurality of metal bumps extending from the bottom surface through the interlayer insulating film and having a first end projecting from the top surface to a first height from the top surface, wherein the top surface of the interlayer insulating film contacts a plurality of metal bumps at a first height lower than the height of the plurality of metal bumps, and the insulating film is curved from the first height to a lower height among the plurality of metal bumps.

2. A member for interconnecting wiring films comprising an interlayer insulating film and a plurality of metal bumps extending through the interlayer insulating film, each being used for interconnecting wiring films of a multilayer wiring substrate and having a first end projecting above the top surface of the interlayer insulating film, wherein said plurality of metal bumps are made of copper having a purity of at least 99.9%, each of said plurality of metal bumps protrudes above the top surface by a distance in the range from approximately 15 to approximately 45 micrometers (μm), and the first end and a second end of said metal bumps have an average surface roughness of less than or equal to 0.5 μm.

3. The member for interconnecting wiring films according to claim 1 or 2, wherein said interlayer insulating film includes a core made of a non-thermoplastic film and said interlayer insulating film further includes one of a first coating having a thickness in the range from approximately 1 to approximately 8 micrometers (μm) and including first and second thermoplastic polyimide resin films opposed to the core or a second coating having a thickness in the range from approximately 1 to 8 micrometers (μm) and including first and second epoxy resin films opposed to the core.

4. The member for interconnecting wiring films according to claim 1, wherein said non-thermoplastic film includes a non-thermoplastic polyimide resin having a thickness in the range from approximately 10 to 70 micrometers (μm).

5. The member for interconnecting wiring films according to claims 1 and 2, wherein said non-thermoplastic film includes a glass epoxy resin having a thickness in the range from approximately 30 to approximately 100 micrometers (μm).

6. A method for manufacturing a member for interconnecting wiring films, comprising:
providing a layered structure including a first surface, a second surface opposite to the first surface, a photoresist film covering the first surface, and a carrier layer covering the second surface;
patterning the photoresist film;
etching a metal film by using the patterned photoresist film as a mask to form a plurality of metal layers having a first end on the side opposite to the carrier layer and protruding from the carrier layer;
removing the patterned photoresist film;
pressing an interlayer insulating film against first ends of a plurality of metal bumps;
polishing the interlayer insulating film to expose the first ends of the plurality of metal bumps; and
removing the carrier layer;
wherein the metal film is substantially made of a copper having a purity of at least 99.9% and the first ends of the plurality of metal bumps and second ends of the plurality of metal bumps on the side opposite to the first ends have an average surface roughness of less than or equal to 0.5 μm.

7. A method for manufacturing member for interconnecting wiring films, comprising:
providing a layered structure including a first surface, a second surface opposite to the first surface, a photoresist film covering the first surface, and carrier layer covering the second surface and being connected to the second surface by an adhesive layer;
patterning the photoresist film;
etching a metal film by using the patterned photoresist film as a mask to form a plurality of metal layers having a first end on the side opposite to the carrier layer and protruding from the carrier layer;
removing the patterned photoresist film;
exposing regions of the adhesive layer between a plurality of metal bumps to ultraviolet light (UV) to reduce the adhesive force of the adhesive layer;
pressing an interlayer insulating film against first ends of the plurality of metal bumps;
polishing the interlayer insulating film to expose first ends of a plurality of metal bumps;
exposing the adhesive layer to ultraviolet light through the carrier layer to reduce the adhesive force between the adhesion layer and the plurality of metal bumps; and
removing the carrier layer from the metal layer while or after the adhesive layer is exposed to ultraviolet light through the carrier layer.

8. The method for manufacturing a member for interconnecting wiring films according to claims 6 and 7, wherein said interlayer insulating film includes a core having a non-plastic film, and one of a first coating having first and second thermoplastic polyimide resin layers opposed to the core or a second coating having first and second epoxy resin layers opposed to the core.

9. The method for manufacturing a wiring film interconnection member according to claim 8, wherein each of the first and second thermoplastic polyimide resin layers or each of the first and second thermoplastic polyimide resin layer has a thickness in the range from approximately 1 to 8 micrometers (μm).

10. The method for manufacturing a member for interconnecting wiring films according to claim 8, wherein the non-thermoplastic film includes a non-thermoplastic polyimide resin having a thickness in the range from approximately 10 to 65 micrometers (μm).

11. The method for manufacturing a member for interconnecting wiring films according to claims 6 and 7, wherein the interlayer insulating film is a glass epoxy resin film having a thickness in the range from approximately 30 to 100 micrometers (μm).

12. The method for manufacturing a member for interconnecting wiring films according to claims 6, 7, 8, 9, 10, and 11, wherein said carrier layer includes a polyester film having a thickness in the range from approximately 25 to 50 micrometers (μm), an initial adhesive force in the range from approximately 10 to 30 N/25 mm and an adhesive force of approximately 0.15 N/25 mm after exposure to ultraviolet light UV.

13. A member used for interconnecting microelectronic component conductors, comprising: an insulating film having a bottom surface and an top surface opposite to the bottom surface; and a plurality of metal bumps extending from the bottom surface through the insulating film and having a first end protruding from the top surface to determine the height of the metal bumps from the top surface; wherein the top surface of the insulating film is curved so as to contact the plurality of metal bumps at a first height lower than the height of the metal bumps and the insulating film is curved between the heights of the plurality of metal bumps downward from the heights of the metal bumps.

14. The member according to claim 13, wherein said plurality of metal bumps are substantially made of copper.

15. The member according to claim 13, wherein said insulating film includes a non-thermoplastic film.

16. The member according to claim 13, wherein said insulating film includes non-thermoplastic film and a thermoplastic film.

17. The member according to claim 13, wherein said insulating film includes a non-thermoplastic polyimide resin film and a thermoplastic polyimide resin film.

18. The member according to claim 13, wherein said plurality of metal bumps are made of copper having a purity of at least 99.9%, the first end of each of said plurality of metal bumps has an average roughness of less than or equal to 0.05 μm, and a second end of each of said plurality of metal bumps on the side opposite to the first end has an average roughness of less than or equal to 0.05 μm.

19. The member according to claim 13, wherein the first end of each of said plurality of metal bump protrudes above the top surface of said insulating film by 15 μm or more.

20. A method for manufacturing a member used for providing a conductor interconnecting member for microelectronic components, comprising:
providing a layered structure including a first surface, a second surface opposite to the first surface, a photoresist film covering the first surface, and a carrier layer covering the second surface;
patterning the photoresist film;
etching a metal film by using the patterned photoresist film as a mask to form a plurality of metal bumps protruding from the carrier layer and having a first end on the side opposite to the carrier layer;
removing the patterned photoresist film;
pressing an insulating film against first ends of the plurality of metal bumps;
polishing the insulating film to expose the first ends of the plurality of metal bumps; and
removing the carrier layer;
wherein the metal film is made of a copper having a purity of at least 99.9% and the first ends of the plurality of metal bumps and second ends of the plurality of metal bumps on the side opposite to the first ends have an average surface roughness of less than or equal to 0.5 μm.

21. A method for manufacturing a member used for providing a conductor interconnecting member for microelectronic components, comprising:
providing a layered structure including a first surface, a second surface opposite to the first surface, a photoresist film covering the first surface, and a carrier layer covering the second surface;
patterning the photoresist film;
etching a metal film by using the patterned photoresist film as a mask to form a plurality of metal bumps protruding from the carrier layer and having a first end on the side opposite to the carrier layer;
removing the patterned photoresist film;
exposing an adhesive region to ultraviolet light UV to reduce the adhesive force of an adhesive layer between the plurality of metal bumps;
pressing an insulating film against the first ends of the plurality of metal bumps;
polishing the insulating film to expose the first ends of the plurality of metal bumps; and
exposing the adhesive layer to ultraviolet light UV through the carrier layer to reduce the adhesive force between the adhesion layer and the plurality of metal bumps, and removing the carrier layer from the metal bumps while or after the adhesive layer is exposed to ultraviolet light bumps through the carrier layer.
